(19) United States
(12) Patent Application Publication
(10) Pub. No.: US 2009/0053881 A1
(43) Pub. Date: Feb. 26, 2009

(54) METHOD OF FORMING DIELECTRIC LAYER OF SEMICONDUCTOR MEMORY DEVICE

(75) Inventor: Jae Mun KIM, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/132,553

(22) Filed: Jun. 3, 2008

(30) Foreign Application Priority Data
Aug. 20, 2007 (KR) 10-2007-83343

(51) Int. Cl. H01L 21/28; H01L 21/314

(52) U.S. Cl. 438/591; 438/763; 257/E21.19; 257/E21.266

(57) ABSTRACT

A method of forming a dielectric layer of a semiconductor memory device is provided. The method includes forming a first insulating layer over a semiconductor substrate, performing a first plasma treatment process in order to densify a film of the first insulating layer, and forming a high-k insulating layer, which has a dielectric constant higher than that of the first insulating layer, on the first insulating layer. After second insulating layer is formed on the high-k insulating layer. A second plasma treatment process is performed in order to densify a film of the second insulating layer.

### CROSS-REFERENCES TO RELATED APPLICATIONS

The present application claims priority to Korean patent application number 10-2007-0083343, filed on Aug. 20, 2007, which is incorporated by reference in its entirety.

### BACKGROUND OF THE INVENTION

The present invention relates to a method of forming a dielectric layer of a semiconductor memory device and, more particularly, to a method of forming a dielectric layer of a semiconductor memory device with improved electrical characteristics.

Among semiconductor memory devices, a flash memory device is described as an example. In general, the flash memory device has a structure in which a tunnel insulating layer, a floating gate, a dielectric layer and a control gate are stacked over a semiconductor substrate. The tunnel insulating layer and the dielectric layer function to isolate the floating gates. More specifically, the tunnel insulating layer functions to control tunneling of electrons between the semiconductor substrate and the floating gate, and the dielectric layer functions to control coupling between the floating gate and the control gate.

The dielectric layer has a structure in which a first insulating layer, a second insulating layer and a third insulating layer are sequentially stacked. The first and third insulating layers are formed of an oxide layer and the second insulating layer is formed of a nitride layer. The oxide layer can be formed of a DCS-HTO (DiChloroSilane High Temperature Oxide) layer that makes gases SiCl₂H₂ and N₂O₂ react to each other.

The dielectric layer of this structure has become easy to generate the leakage current as semiconductor memory devices are high integrated. To solve this problem, a high-k (high dielectric) layer has been used as the second insulating layer instead of the nitride layer.

However, in the case where the second insulating layer is formed of a high-k layer, the densification of the oxide layer is lowered if the first and third insulating layer formed on the upper and lower sides are formed of the DCS-HTO layer. This may degrade electrical characteristics.

### BRIEF SUMMARY OF THE INVENTION

The present invention is directed towards semiconductor memory devices with improved electrical characteristics by performing a subsequent treatment process in order to make dense the film quality, after a first insulating layer and a third insulating layer are formed of a DCS-HTO layer, in a process of forming a dielectric layer having a stacked structure of the first insulating layer, a second insulating layer and the third insulating layer.

In accordance with an aspect of the present invention, there is a method of forming a dielectric layer of a semiconductor memory device. The method includes forming a first insulating layer over a semiconductor substrate, performing a first plasma treatment process in order to densify a film quality of the first insulating layer, and forming a high-k (dielectric constant) insulating layer, which has a dielectric constant higher than that of the first insulating layer, on the first insulating layer. The method further includes forming a second insulating layer on the high-k insulating layer, and performing a second plasma treatment process in order to densify a film quality of the second insulating layer.

The first and second insulating layers may include a DCS-HTO (DiChloroSilane High Temperature Oxide) layer. The DCS-HTO layer may be formed by making gases SiCl₂H₂ and N₂O₂ react to each other.

The formation of the first and second insulating layers may be carried out using a LP-CVD (Low-Pressure Chemical Vapor Deposition). The LP-CVD method may be performed at a temperature in a range of 600 to 900 degrees Celsius. Each of the first and second insulating layers may be formed to a thickness in a range of 20 to 50 angstrom.

The first and second plasma treatment processes may be performed using a mixed gas of Ar, O₂ and H₂. The first and second plasma treatment processes may be performed using power in a range of 1 kW to 5 kW at a pressure in a range of 0.01 Torr to 10 Torr and at a temperature in a range of 300 to 600 degrees Celsius.

The high-k insulating layer may include any one or two or more of Al₂O₃, HfO₂, ZrO₂, SiON, La₂O₃, Y₂O₃, TiO₂, CeO₂, N₂O₃, Ta₂O₅, BaTiO₃, SrTiO₃, BST and PZT.

The high-k insulating layer may be formed of a metal silicate layer in which metal, silicon and oxygen are combined.

The metal silicate layer may include Hf-silicate, Zr-silicate, Al-silicate, La-silicate, Ce-silicate, Y-silicate, Ta-silicate or Ti-silicate.

The high-k insulating layer may be formed to a thickness in a range of 20 to 150 angstrom. The high-k insulating layer may be formed using an ALD (Atomic Layer Deposition) method. The ALD method may be performed using O₂, H₂O or O₃, or a mixed gas of them as a reaction gas. The ALD method may be performed at a temperature in a range of 200 to 500 degrees Celsius.

A tunnel insulating layer and a first conductive layer may be formed over the semiconductor substrate before the first insulating layer is formed. A second conductive layer may be formed on the third insulating layer after the second plasma treatment process is performed.

### BRIEF DESCRIPTION OF THE DRAWINGS

FIGS. 1A to 1E are sectional views illustrating a method of forming a dielectric layer of a semiconductor memory device in accordance with the present invention.

### DESCRIPTION OF SPECIFIC EMBODIMENTS

Now, a specific embodiment according to the present invention will be described with reference to the accompanying drawings. However, the present invention is not limited to the disclosed embodiment, but may be implemented in various manners. The embodiment is provided to complete the disclosure of the present invention and to allow those having ordinary skill in the art to understand the scope of the present invention. The present invention is defined by the category of the claims.

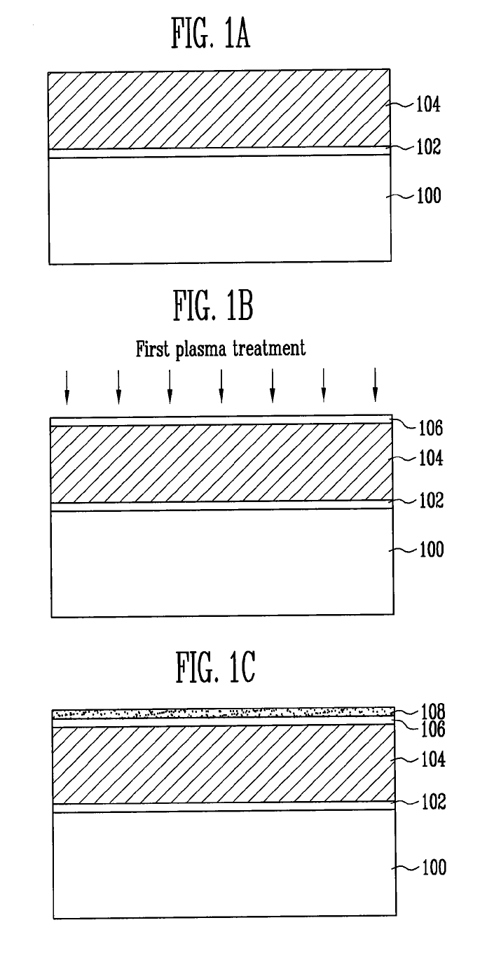

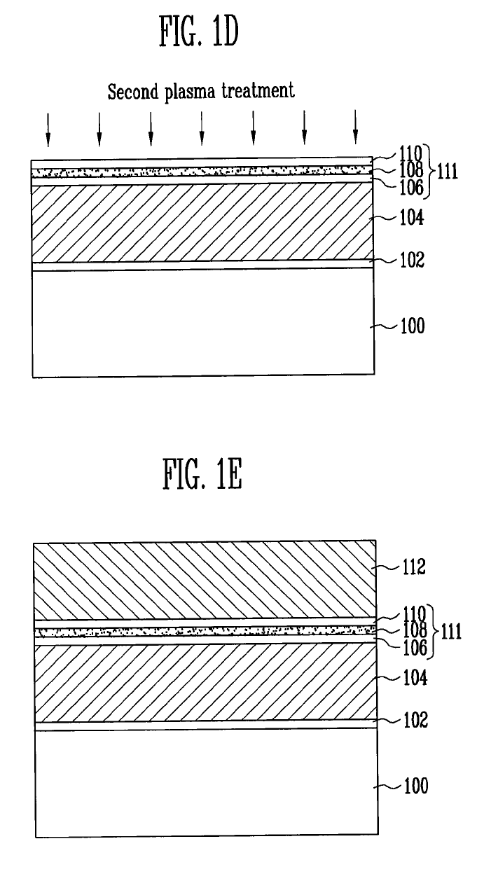

FIGS. 1A to 1E are sectional views illustrating a method of forming a dielectric layer of a semiconductor memory device in accordance with the present invention.

Referring to FIG. 1A, a tunnel insulating layer 102 and a first conductive layer 104 for a floating gate are sequentially formed over a semiconductor substrate 100. The tunnel insulating layer 102 may be formed of an oxide layer and the first conductive layer 104 may be formed of a polysilicon layer.

Although not shown in the drawing, isolation layers are formed within trenches after the trenches are formed. More specifically, for example, an isolation mask pattern is formed on the first conductive layer 104. The first conductive layer 104 and the tunnel insulating layer 102 are patterned by performing an etch process along the isolation mask pattern. An exposed semiconductor substrate 100 is etched to thereby form the trenches. The isolation layers are formed within the trenches and the isolation mask pattern is then removed. The EFH (Effective Field oxide Height) of the isolation layer is then controlled.

Referring to FIG. 1B, a first insulating layer 106 for a dielectric layer is formed on the first conductive layer 104. More specifically, the first insulating layer 106 can be formed using a LP-CVD (Low-Pressure Chemical Vapor Deposition) at a temperature in a range of 600 to 900 degrees Celsius. The first insulating layer 106 is a DCS-HTO (DiChloroSilane High Temperature Oxide) layer, which is formed by making gases SiCl₂H₂ and N₂O₂ react to each other and may be formed to a thickness of in a range 20 to 50 angstrom.

After the first insulating layer 106 is formed, a first plasma treatment process for densifying the film quality of the first insulating layer 106 is performed. The first plasma treatment process is a plasma oxidization process employing a mixed gas of Ar, O₂ and H₂, and may be performed using power of 1 kW to 5 kW at a pressure in a range of 0.01 Torr to 10 Torr and at a temperature in a range of 300 to 600 degrees Celsius.

Referring to FIG. 1C, a second insulating layer 108 for a dielectric layer is formed on the first insulating layer 106. The second insulating layer 108 may be formed using an ALD Atomic Layer Deposition). Here, the ALD method can be performed using a reaction gas of O₂, H₂O or O₃, or a mixed gas of them when forming the second insulating layer 108.

The second insulating layer 108 may be formed of a high-k layer or a metal silicate layer at a uniform thickness in a range of 20 angstrom to 150 angstrom. The ALD method ALD may be performed at a temperature in a range of 200 to 500 degrees Celsius. In this case, the occurrence of the leakage current can be prevented by using the high-k layer, having the dielectric constant of 3.9 or more, as the second insulating layer 108. The high-k material may include, for example, any one of Al₂O₃, HfO₂, ZrO₂, SiON, La₂O₃, Y₂O₃, TiO₂, CeO₂, N₂O₃, Ta₂O₅, BaTiO₃, SrTiO₃, BST and PZT. Further, the metal silicate layer is made of material in which metal, silicon and oxygen are combined and may include, for example, Hf-silicate, Zr-silicate, Al-silicate, La-silicate, Ce-silicate, Y-silicate, Ta-silicate or Ti-silicate.

Referring to FIG. 1D, a third insulating layer 110 for a dielectric layer is formed on the second insulating layer 108. More specifically, the third insulating layer 110 may be formed using a LP-CVD method at a temperature in a range of 600 to 900 degrees Celsius. The third insulating layer 110 is a DCS-HTO layer which is formed by making gases SiCl₂H₂ and N₂O₂ react to each other and may be formed to a thickness in a range of 20 to 50 angstrom.

After the third insulating layer 110 is formed, a second plasma treatment process for densifying the film quality of the third insulating layer 110 is carried out. The second plasma treatment process is a plasma oxidization process in which gases Ar, O₂ and H₂ are mixed and may be performed using power of 1 kW to 5 kW at a pressure in a range of 0.01 Torr to 10 Torr and at a temperature in a range of 300 to 600 degrees Celsius.

Thus, the first insulating layer 106, the second insulating layer 108 and the third insulating layer 110 constitute a dielectric layer 111.

Referring to FIG. 1E, a second conductive layer 112 for a control gate is formed on the dielectric layer 111. Subsequent processes are then performed.

According to the above technology, the second insulating layer 108 is made of the high-k material. Thus, a leakage current characteristic and a charge retention characteristic can be improved in the same ETO (Equivalent Oxide Thickness) when compared with SiO₂. Further, since the second insulating layer 108 is formed at a low temperature of 500 degrees Celsius or less (200 to 500 degrees Celsius), a reduction in the reliability of the tunnel insulating layer 102 due to thermal budget can be prevented.

Further, the first and third insulating layers 106 and 110 may be formed using the DCS-HTO layer after the plasma oxidization process is performed. However, the plasma oxidization process according to the present invention presents a method of converting an oxide layer into an oxide layer having a dense film quality through a plasma treatment process when the oxide layer does not have a dense film quality. This can make the DCS-HTO layer (the oxide layer) dense through radical oxygen ions. Accordingly, the breakdown voltage can be increased, the leakage current can be prevented, and the threshold voltage disturbance characteristic can be improved.

As described above, according to certain embodiments the present invention, in the process of forming the dielectric layer having a stacked structure of the first insulating layer, the second insulating layer and the third insulating layer, the first insulating layer and the third insulating layer are formed of the DCS-HTO layer and a subsequent treatment process is then performed. Accordingly, the film quality of the dielectric layer can be made dense.

Further, the second insulating layer is formed of a high-k layer. Accordingly, the occurrence of the leakage current can be prevented, the breakdown voltage can be increased, and the threshold voltage disturbance characteristic can be improved. In addition, a leakage current characteristic and a charge retention characteristic can be improved in the same ETO when compared with SiO₂.

Incidentally, since the dielectric layer is formed at a low temperature, a reduction in the reliability of the tunnel insulating layer due to thermal budget can be prevented.

The embodiment disclosed herein has been proposed to allow a person skilled in the art to easily implement the present invention, and the person skilled in the part may implement the present invention by a combination of embodiments. Therefore, the scope of the present invention is not limited by or to the embodiment as described above, and should be construed to be defined only by the appended claims and their equivalents.

What is claimed is:

1. A method of forming a dielectric layer of a semiconductor memory device, the method comprising:
forming a first insulating layer over a semiconductor substrate;
performing a first plasma treatment process in order to densify a film of the first insulating layer;
forming a high-k (dielectric constant) insulating layer, which has a dielectric constant higher than that of the first insulating layer, on the first insulating layer;
forming a second insulating layer on the high-k insulating layer; and
performing a second plasma treatment process in order to densify a film of the second insulating layer.

2. The method of claim 1, wherein the first and second insulating layers are a DCS-HTO (DiChloroSilane High Temperature Oxide) layer.

3. The method of claim 2, wherein the DCS-HTO layer is formed by making gases SiCl₂H₂ and N₂O₂ react to each other.

4. The method of claim 1, wherein the formation of the first and second insulating layers is carried out using a LP-CVD (Low-Pressure Chemical Vapor Deposition) method.

5. The method of claim 4, wherein the LP-CVD method is performed at a temperature in a range of 600 to 900 degrees Celsius.

6. The method of claim 1, wherein each of the first and second insulating layers is formed to a thickness in a range of 20 to 50 angstrom.

7. The method of claim 1, wherein the first and second plasma treatment processes are performed using a mixed gas of Ar, O₂ and H₂.

8. The method of claim 1, wherein the first and second plasma treatment processes are performed using power of 1 kW to 5 kW at a pressure in a range of 0.01 Torr to 10 Torr and at a temperature in a range of 300 to 600 degrees Celsius.

9. The method of claim 1, wherein the high-k insulating layer includes one selected from a group consisting of Al₂O₃, HfO₂, ZrO₂, SION, La₂O₃, Y₂O₃, TiO₂, CeO₂, N₂O₃, Ta₂O₅, BaTiO₃, SrTiO₃, BST, PZT and a combination thereof.

10. The method of claim 8, wherein the high-k insulating layer is formed of a metal silicate layer in which metal, silicon and oxygen are combined.

11. The method of claim 10, wherein the metal silicate layer includes Hf-silicate, Zr-silicate, Al-silicate, La-silicate, Ce-silicate, Y-silicate, Ta-silicate or Ti-silicate.

12. The method of claim 1, wherein the high-k insulating layer is formed to a thickness in a range of 20 to 150 angstrom.

13. The method of claim 1, wherein the high-k insulating layer is formed using an ALD (Atomic Layer Deposition) method.

14. The method of claim 13, wherein the ALD method is performed using O₂, H₂O or O₃, or a mixed gas of them as a reaction gas.

15. The method of claim 13, wherein the ALD method is performed at a temperature in a range of 200 to 500 degrees Celsius.

16. The method of claim 1, further comprising forming a tunnel insulating layer and a first conductive layer over the semiconductor substrate before the first insulating layer is formed.

17. The method of claim 1, further comprising forming a second conductive layer on the second insulating layer after the second plasma treatment process is performed.

18. A method of forming a dielectric layer of a semiconductor memory device, the method comprising:
forming a first insulating layer over a semiconductor substrate;
performing a first plasma treatment process in order to densify a film of the first insulating layer;
forming a high-k insulating layer, which has a dielectric constant higher than that of the first insulating layer, on the first insulating layer; and
forming a second insulating layer on the high-k insulating layer.

19. A method of forming a dielectric layer of a semiconductor memory device, the method comprising:
forming a first insulating layer over a semiconductor substrate;
forming a high-k insulating layer, which has a dielectric constant higher than that of the first insulating layer, on the first insulating layer;
forming a second insulating layer on the high-k insulating layer; and
performing a first plasma treatment process in order to densify a film of the second insulating layer.
